(19) United States
(12) Patent Application Publication
(10) Pub. No.: US 2024/0234433 A1
(43) Pub. Date: Jul. 11, 2024

(54) THIN FILM TRANSISTOR ARRAY SUBSTRATE INCLUDING OXIDE SEMICONDUCTOR PATTERN AND DISPLAY DEVICE INCLUDING SAME

(71) Applicant: LG Display Co., Ltd., Seoul (KR)

(72) Inventor: SangHoon Jeong, Paju-si (KR)

(73) Assignee: LG Display Co., Ltd., Seoul (KR)

(21) Appl. No.: 18/396,314

(22) Filed: Dec. 26, 2023

(30) Foreign Application Priority Data
Jan. 6, 2023 (KR) 10-2023-0002211

(51) Int. Cl. H01L 27/12; H01L 25/16

(52) U.S. Cl. CPC H01L 27/1233; H01L 25/167

(57) ABSTRACT

A thin film transistor array substrate of the present disclosure includes a substrate including an active area and a non-active area disposed in the vicinity of the active area, and a plurality of pixels disposed in the active area, in which each pixel includes a plurality of sub pixels, each sub pixel includes a driving thin film transistor including an oxide semiconductor pattern, and the driving thin film transistor in the pixel includes sub pixels having different ratios of a width to a length of a channel of the driving thin film transistor. By doing this, provided is a display device in which a color deviation between each sub pixels, as it is used, is reduced to stabilize a color of the display device.

### CROSS-REFERENCE TO RELATED APPLICATIONS

This application claims the priority of Korean Patent Application No. 10-2023-0002211 filed on Jan. 6, 2023, in the Korean Intellectual Property Office, the disclosure of which is incorporated herein by reference.

### BACKGROUND

### Technical Field

The present disclosure relates to a thin film transistor array substrate including an oxide semiconductor pattern, and more particularly, to a thin film transistor array substrate in which a thin film transistor expresses a low gray scale of a thin film transistor, a leakage current is blocked, and a color deviation caused by the difference in degradation as it is used is improved, and a display device including the same.

### Discussion of the Related Art

Recently, in accordance with the development of the multimedia, importance of a flat display device is increased. In response to this, flat display devices, such as a liquid crystal display device, a plasma display device, or an organic light emitting display device, are being commercialized. Among such flat display devices, an organic light emitting display device is being currently widely used because of its high response speed, high luminance, and wide viewing angle.

In the organic light emitting display device, a plurality of pixels is disposed in a matrix shape and each pixel includes a light emitting diode part represented by an organic light emitting layer and a a pixel circuit part represented by a thin film transistor. The pixel circuit part includes a driving thin film transistor (TFT) which supplies a driving current to operate an organic light emitting diode and a switching thin film transistor (TFT) which supplies a gate signal to the driving thin film transistor.

Further, in the non-active area of the organic light emitting display device, a gate driving circuit unit which supplies a gate signal to a pixel may be disposed.

As described above, the present disclosure relates to an array substrate and a display device including the same. The array substrate includes a driving thin film transistor which is disposed in a pixel, specifically, in the pixel circuit part of a sub pixel and blocks a leakage current in an off-state. The driving thin film transistor freely enables gradation expression at a low gray scale. Additionally, the driving thin film transistor solves the problem to express with an accurate color to be difficult, because a threshold voltage of the driving thin film transistor is changed as it is used.

### SUMMARY

Accordingly, embodiments of the present disclosure are directed to a thin film transistor array substrate including an oxide semiconductor pattern and a display device including the same that substantially obviate one or more of the problems due to limitations and disadvantages of the related art.

An aspect of the present disclosure is to provide an array substrate including a thin film transistor which has a high blocking effect of a leakage current in an off-state of a driving thin film transistor disposed in a pixel, ensures a threshold voltage higher than a target voltage, and freely expresses the gradation at a low gray scale, and uses an oxide semiconductor pattern having an increased S-factor as an active layer, and a display device including the same. Further, another aspect of the present disclosure is to enable optimal color reproduction by differently designing a structure of a channel of a driving thin film transistor for each of red, green, and blue to solve the problem in that the threshold voltage is changed due to the continuous use of the driving thin film transistor disposed in each sub pixel so that it is difficult to express an accurate color.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin substrate comprises film transistor array a substrate including an active area and a non-active area disposed in the vicinity of the active area; and a plurality of pixels disposed in the active area, in which each pixel includes a plurality of sub pixels, each sub pixel includes a driving thin film transistor including an oxide semiconductor pattern, and the driving thin film transistor in the pixel includes sub pixels having different ratios of a width to a length of a channel of the driving thin film transistor.

The pixel includes red, green, and blue sub pixels. A ratio of a width to a length of a channel of a driving thin film transistor included in the blue sub pixel of the pixel may be smaller than a ratio of a width to a length of a channel of a driving thin film transistor included in the other sub pixel in the pixel.

A length of a channel of the driving thin film transistor included in the blue sub pixel of the pixel may be larger than a length of a channel of the driving thin film transistor included in the other color sub pixels, that is, the red and green sub pixels in the pixel.

Other detailed matters of the exemplary embodiments are included in the detailed description and the drawings.

According to the present disclosure, a driving thin film transistor and a switching thin film transistor including an oxide semiconductor pattern in a pixel are included so that the leakage current in an off-state is blocked to reduce power consumption. A sub pixel of the present disclosure is designed such that a ratio of a width to a length of a channel of a driving thin film transistor disposed in red, green, and blue sub pixels to correct the degradation problem due to the use of each sub pixel. Accordingly, a display device in which variation of a color coordinate value is minimized as the display device is consistently used to maintain an image quality is provided.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic block diagram of a display device according to the present disclosure;

FIG. 2 is a schematic block diagram of a sub pixel of a display device according to the present disclosure;

FIG. 3 is a circuit diagram of a sub pixel of a display device according to the present disclosure;

FIG. 4 is a graph illustrating a phenomenon that a driving thin film transistor in each sub pixel is deteriorated as it is used so that a current is increased over the time;

FIG. 5A is a plan view illustrating a length and a width of a channel of a driving thin film transistor in red, green, and blue sub pixels;

FIG. 5B is a table illustrating a change in the amount of current of a driving thin film transistor after elapse of a predetermined time, when a length and a width of a channel of a driving thin film transistor in red, green, and blue sub pixels are the same;

FIG. 5C is a plan view illustrating a length and a width of a channel of a driving thin film transistor when a length and a width of a channel of a driving thin film transistor in red, green, and blue sub pixels are differently designed;

FIG. 5D is a table illustrating a change in the amount of current after elapse of a predetermined time when a length and a width of a channel of a driving thin film transistor are differently designed as illustrated in FIG. 5C;

FIG. 6A is a cross-sectional view of one thin film transistor disposed in a gate driving circuit unit of a non-active area, and a driving thin film transistor, a switching thin film transistor, and a storage capacitor disposed in an active area, as an exemplary embodiment of the present disclosure;

FIG. 6B is a cross-sectional view illustrating a parasitic capacitance generated in a driving thin film transistor of the present disclosure; and

FIG. 6C is a circuit diagram illustrating a relationship with a parasitic capacitance illustrated in FIG. 6B.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a first example embodiment of the present disclosure will be described in detail with reference to the accompanying drawings.

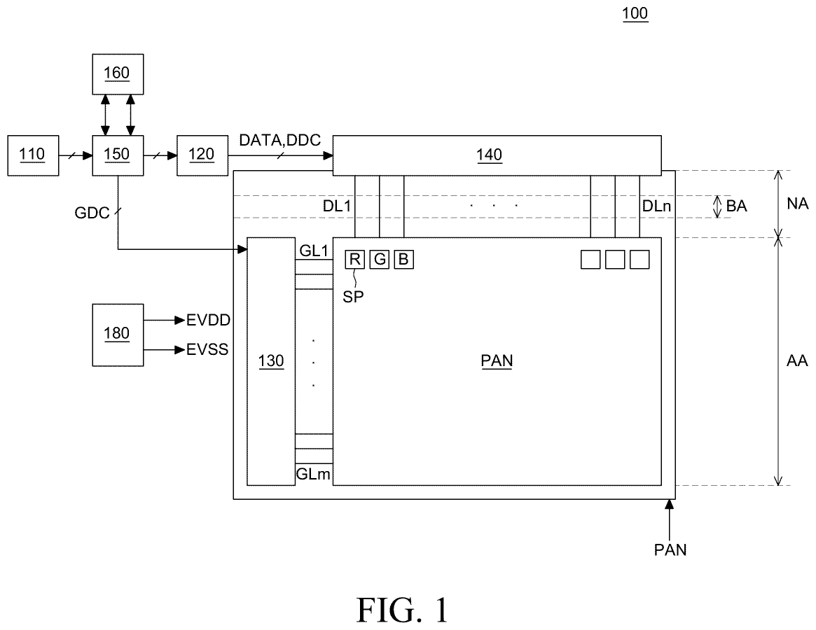

FIG. 1 is a schematic block diagram of a display device 100 according to the present disclosure.

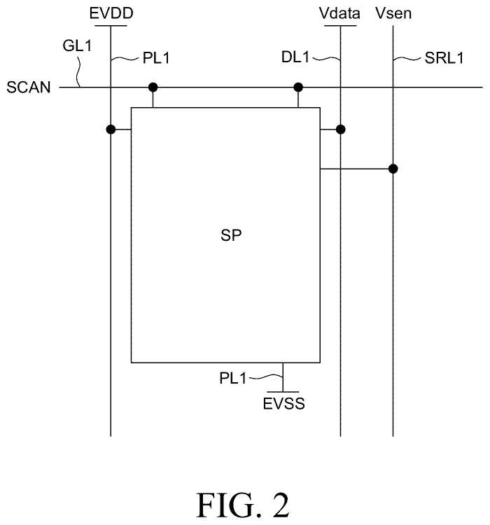

FIG. 2 is a schematic block diagram of a sub pixel SP illustrated in FIG. 1.

As illustrated in FIG. 1, the display device 100 is configured to include a display panel PAN in which an image processor 110, a deterioration compensating unit 150, a memory 160, a timing controller 120, a data driver 140, a power supply unit 180, and a gate driver 130 are formed. Specifically, the non-active area NA of the display panel PAN includes a bending area BA. The display panel PAN may be bent in the bending area BA to reduce a bezel.

The image processor 110 outputs a driving signal for driving various devices together with image data supplied from the outside.

The deterioration compensating unit 150 modulates input image data Idata of each sub pixel SP of a current frame based on a sensing voltage Vsen supplied from the data driver 140, and then supplies the modulated image data Mdata to the timing controller 120.

The timing controller 120 generates and outputs a gate timing control signal GDC for controlling an operation timing of the gate driver 130 and a data timing control signal DDC for controlling an operation timing of the data driver 140 based on the driving signal input from the image processor 110.

The gate driver 130 outputs the scan signal to the display panel PAN in response to the gate timing control signal GDC supplied from the timing controller 120. The gate driver 130 outputs a scan signal through the plurality of gate lines GL1 to GLm. Specifically, the gate driver 130 may be formed with a gate in panel (GIP) structure by directly laminating a thin film transistor on a substrate in the organic electroluminescent display device 100. The GIP may include a plurality of circuits such as a shift register or a level shifter.

The data driver 140 outputs the data voltage to the display panel PAN in response to the data timing control signal DDC input from the timing controller 120. The data driver 140 outputs a data voltage through a plurality of data lines DL1 to DLn.

The power supply unit 180 outputs a high potential driving voltage EVDD and a low potential driving voltage EVSS to supply to the display panel PAN. The high potential driving voltage EVDD and the low potential driving voltage EVSS are supplied to the display panel PAN through a power line.

The display panel PAN displays images in response to a data voltage and a scan signal supplied from the data driver 140 and the gate driver 130 which may be disposed in the non-active area NA, and a power supplied from the power supply unit 180.

The active area AA of the display panel PAN is configured by a plurality of sub pixels SP to display actual images. The sub pixel SP includes a red sub pixel, a green sub pixel, and a blue sub pixel, or includes a white (W) sub pixel, a red (R) sub pixel, a green (G) sub pixel, and a blue (B) sub pixel. At this time, all the W, R, G, B sub pixels SP may be formed with the same area, or may also be formed with different areas. Red, green, and blue sub pixels or red, green, blue, and white sub pixels may form one set to configure on pixel.

In the memory 160, a look up table for a degradation compensation gain is stored and a degradation compensating time of the organic light emitting diode of a sub pixel SP is stored. At this time, the degradation compensating time of the organic light emitting diode may be a number of times of driving an organic light emitting display panel or a driving time thereof.

In the meantime, as illustrated in FIG. 2, one sub pixel SP may be connected to a gate line GL1, a data line DL1, a sensing voltage read out line SRL1, and a power line PL1. In the sub pixel SP, the number of transistors and capacitors and a driving method are determined according to a configuration of a circuit.

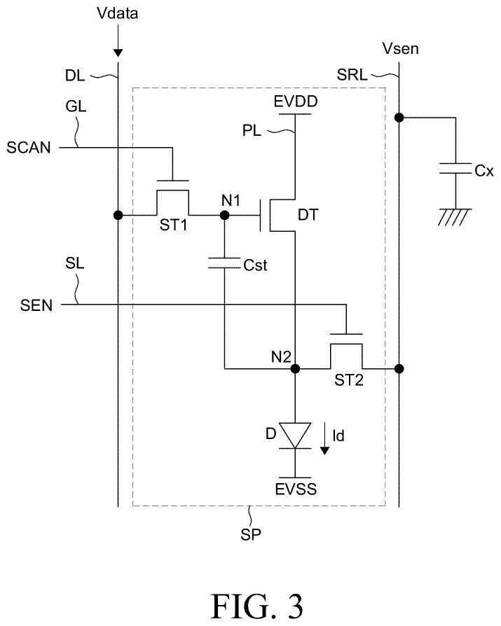

FIG. 3 is a circuit diagram of a sub pixel SP of a display device 100 according to the present disclosure.

As illustrated in FIG. 3, the display device 100 according to the present disclosure includes a gate line GL, a data line DL, a power line PL, and a sensing line SL which intersect each other to define a sub pixel SP. The sub pixel SP includes a driving thin film transistor DT, a light emitting diode D, a storage capacitor Cst, a first switching thin film transistor ST, and a second switching thin film transistor ST2.

The light emitting diode D may include an anode electrode connected to a second node N2, a cathode electrode connected to an input terminal of a low potential driving voltage EVSS, and an organic light emitting layer located between the anode electrode and the cathode electrode.

The driving thin film transistor DT controls a current Id which flows in the light emitting diode D according to a gate-source voltage Vgs. The driving thin film transistor DT includes a gate electrode connected to a first node N1, a drain electrode which is connected to a power line PL to be supplied with a high potential driving voltage EVDD, and a source electrode connected to the second node N2.

The storage capacitor Cst is connected between the first node N1 and the second node N2.

The first switching thin film transistor ST1 applies a data voltage Vdata charged in the data line DL in response to the gate signal SCAN when the display panel PAN is driven to the first node N1 to turn on the driving thin film transistor DT. At this time, the first switching thin film transistor ST1 includes a gate electrode which is connected to the gate line GL to be supplied with a scanning signal SCAN, a drain electrode which is connected to the data line DL to be supplied with a data voltage Vdata, and a source electrode connected to the first node N1. The first switching thin film transistor ST1 is known to be sensitive more than the other switching thin film transistor in the pixel. Accordingly, it is necessary to easily control the first switching thin film transistor ST1 by increasing a threshold voltage.

The second switching thin film transistor ST2 switches a current between the second node N2 and the sensing voltage read out line SRL in response to the sensing signal SEN to store the source voltage of the second node N2 in a sensing capacitor Cx of the sensing voltage read out line SRL. The second switching thin film transistor ST2 switches a current between the second node N2 and the sensing voltage read out line SRL in response to the sensing signal SEN when the display panel PAN is driven, to reset a source voltage of the driving thin film transistor DT as an initialization voltage Vpre. At this time, the gate electrode of the second switching thin film transistor ST2 is connected to the sensing line SL, the drain electrode is connected to the second node N2, and the source electrode is connected to the sensing voltage read out line SRL.

In the meantime, even though in the drawing, a display device with a 3T1C structure including three thin film transistors and one storage capacitor is illustrated, the display device of the present disclosure is not limited to this structure, but may be applied to various pixel structures, such as 4T1C, 5T1C, 6T1C, 7T1C, and 8T1C.

In the present disclosure, in order to block a leakage current to reduce power consumption and reduce a manufacturing cost, a driving thin film transistor DT and a switching thin film transistor ST-1 which use the oxide semiconductor pattern as an active layer is proposed. When the thin film transistor which utilizes oxide semiconductor is introduced as component of a pixel circuit part, a display device which freely expresses gradation even at a low gray scale may be provided.

However, as the driving thin film transistor using oxide semiconductor pattern is consistently used, the threshold voltage is changed so that a bluish color problem is caused.

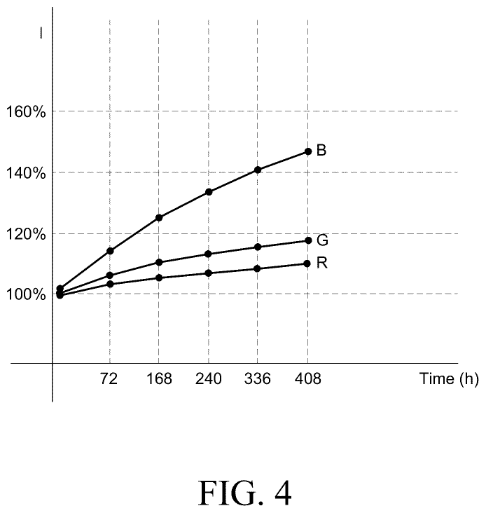

FIG. 4 is a graph illustrating a change in the amount of current over time in each sub pixel, that is, red, green, blue sub pixels, according to a usage time.

Referring to FIG. 4, it may be confirmed that an amount of current of all the red, green, and blue sub pixels is increased in accordance with the elapse of time. It is known that this is because the driving thin film transistor of each sub pixel is exposed to a positive voltage for a long time so that a positive biased temperature stress (PBTS) is given to shift the threshold voltage. Moreover, in the red, green, and blue sub pixels, a degree of PBTS appears different from each other. That is, it may be confirmed that the blue sub pixel has the largest PBTS. As a result, after elapse of a predetermined time, the organic light emitting display device tends to be bluish as a whole.

Accordingly, the present disclosure proposes a display device which minimizes a color change of red, green, blue sub pixels to maintain a stable color tone as a whole even though the usage time is continued.

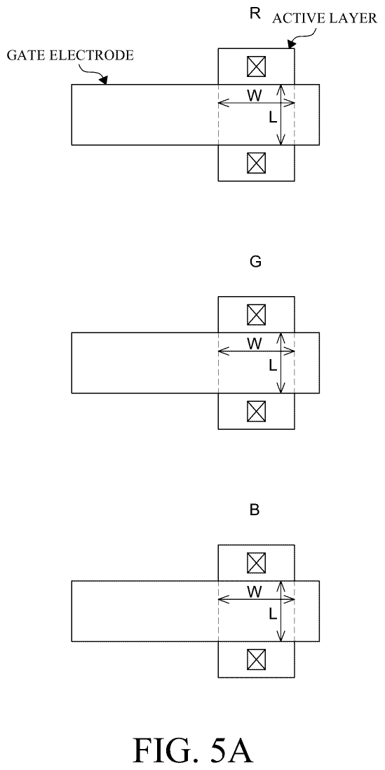

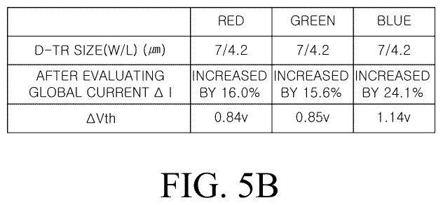

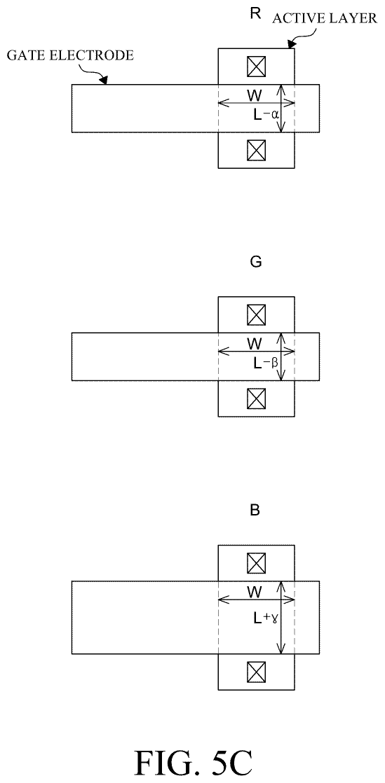

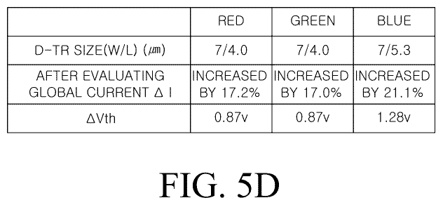

A changed matter of a driving thin film transistor of the present disclosure will be described with reference to FIGS. 5A to 5D.

FIG. 5A illustrates a plan view of a channel of a driving thin film transistor DT embedded in red, green, and blue sub pixels.

An area in which the active layer and the gate electrode overlap becomes a channel region. The channel region has a width W and a length L.

FIG. 5B is a graph illustrating a ratio W/L of a width to a length of a channel of red, green, and blue driving thin film transistors, a change in the amount of current ΔI after evaluation of a global current and a change of a threshold voltage ΔVth. Here, the global current may be considered as a sum of currents which flow in a device at a predetermined time period.

Referring to FIG. 5A, in the red, green, and blue driving thin film transistors, both a width and a length of a channel are the same. In this case, referring to FIG. 5B, it may be confirmed that after elapse of a predetermined time, that is, after the evaluation of the global current, an amount of current of a driving thin film transistor of a red sub pixel increased by 16%, the amount of current of a driving thin film transistor of a green sub pixel increased by 15.6%. Further, the amount of current of a driving thin film transistor of a blue sub pixel increased by 24.1%. It means that after a predetermined usage time, the blue sub pixels show the largest change in the amount of current, which means, as a consequence, that the screen turns bluish. The reason is determined because driving voltages which drive each of the red, green, and blue sub pixels are different from each other, and as a result, a positive biased temperature stress (PBTS) varies over time. Referring to FIG. 5B, it may be confirmed that the variances ΔVth of threshold voltages of a driving thin film transistor of red, blue, and green pixels are different from each other. The driving thin film transistor of the blue sub pixel has the largest variance of the threshold voltage.

The present disclosure recognized the problem. As a consequence, the present disclosure proposes a display device in which a color deviation between each sub pixels is minimized even though the usage time is continued.

An improved structure of a driving thin film transistor will be described with reference to FIGS. 5C and 5D.

The present disclosure proposes to differently design a driving thin film transistor embedded in red, green, blue sub pixels. Specifically, a color deviation between red, green, and blue sub pixels is minimized by changing a ratio of a width to a length of a channel of a driving thin film transistor embedded in the red, green, and blue sub pixels.

Referring to FIG. 5C, a length of a channel of a driving thin film transistor in the red and green sub pixels is reduced, and a length of a channel of a driving thin film transistor in a blue sub pixel is increased by adding a predetermined value. That is, a ratio of a width to a length of a driving thin film transistor in the blue sub pixel is smaller than those of a driving thin film transistor of the red and green sub pixels. The ratio of the width to the length of the channel of the driving thin film transistor included in the blue sub pixel may be the smallest. The length of the channel of the driving thin film transistor included in the blue sub pixel among the pixel may be the largest.

As a result, a variance ΔI of an amount of current of a driving thin film transistor in the red sub pixel after evaluation of a global current increased by 17.2% and a variance of the amount of current of a driving thin film transistor in the green sub pixel after evaluation of a global current increased by 17.0%. Further, a variance of the amount of current of a driving thin film transistor in the blue sub pixel after evaluation of a global current increased by 21.2%. It may be confirmed that after elapse of a predetermined time, all the amounts of driving current are increased in the driving thin film transistors in the red, green, and blue sub pixels, but the deviation is reduced.

The cause may be estimated from the change of the threshold voltage. That is, it may be confirmed that the threshold voltage increased by 1.28 V by reducing the ratio of the width to the length of the channel of the driving thin film transistor in the blue sub pixel, which is significantly increased as compared with the driving thin film transistor in the red and green sub pixels. What the threshold voltage is increased may be understood that the driving thin film transistor operates more insensitively.

That is, in the present disclosure, when the ratio of the width to the length of the channel of the driving thin film transistor is reduced, the driving thin film transistor operates more insensitively, and the color deviation between red, green, and blue sub pixels may be reduced using this operation principle.

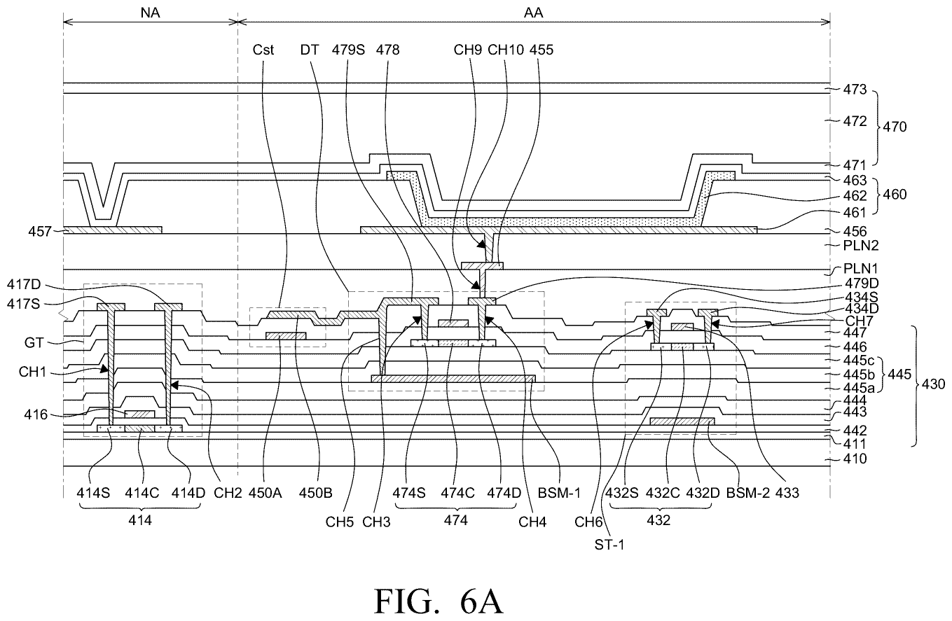

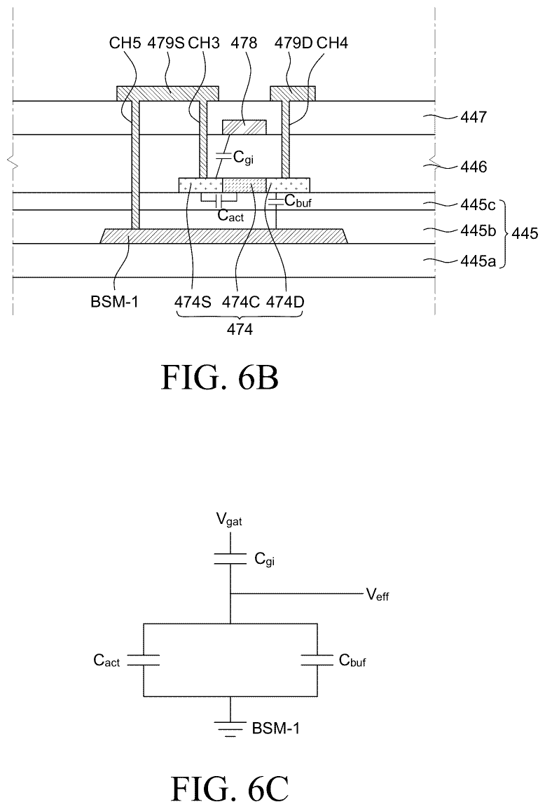

In the meantime, referring to FIGS. 6A to 6C, a cross-sectional structure of a thin film transistor array substrate of the present disclosure will be described with reference to a cross-sectional view of one thin film transistor GT, a driving thin film transistor DT, and a first switching thin film transistor ST-1 and a storage capacitor Cst including an oxide semiconductor pattern, as an exemplary embodiment of the present disclosure. The thin film transistor GT is a thin film transistor for one gate driving circuit, and as a representative of a thin film transistor disposed in the non-active area NA, specifically, in the GIP area, includes a polycrystalline semiconductor pattern. The driving thin film transistor DT is disposed in the subpixel among the active area AA and includes an oxide semiconductor pattern which drives a light emitting diode.

As described above, the pixel circuit parts included in the red, green, and blue sub pixels of the present disclosure have the same circuit configuration. However, a ratio of width to the length of the channel of the driving thin film transistor disposed in each sub pixel may be different from each other.

Accordingly, FIG. 6A illustrates a structure of a sub pixel proposed by the present disclosure by disclosing a cross-sectional structure of one sub pixel among a plurality of sub pixels.

Referring to FIG. 6A, a driving thin film transistor DT and a first switching thin film transistor ST-1 are disposed in the sub pixel on the substrate 410. At this time, even though in FIG. 6A, only the driving thin film transistor DT and one switching thin film transistor ST-1 are disclosed, this is for the convenience of description so that a plurality of switching thin film transistors may be disposed on the actual substrate 410.

Further, in the non-active area NA on the substrate 410, specifically in the GIP area, a plurality of thin film transistors GT for a gate driving circuit which configures a gate driver may be disposed. The thin film transistor GT for a gate driving circuit may use a polycrystalline semiconductor pattern as an active layer. However, this is just an example, so that the thin film transistor GT for a gate driving circuit may use an oxide semiconductor material, such as a first switching thin film transistor ST-1, as an active layer.

Further, in the present exemplary embodiment, it is described that the thin film transistor GT for a gate driving circuit which includes a polycrystalline semiconductor material as an active layer is disposed in the non-active area NA. However, a switching thin film transistor with the same structure as the thin film transistor GT for a gate driving circuit may also be disposed in a sub pixel of the active area.

However, the thin film transistor GT for a gate driving circuit disposed in the non-active area NA and the switching thin film transistor disposed in the active area have different types of impurities to be doped to be differently configured, like the n-type thin film transistor or the p-type thin film transistor.

In the meantime, a plurality of thin film transistors disposed in the gate driver may be configured by a CMOS in which the thin film transistor including a polycrystalline semiconductor material as an active layer and a thin film transistor including an oxide semiconductor material as an active layer form one pair.

Hereinafter, it is described that the thin film transistor for a gate driving circuit which uses a polycrystalline semiconductor material as an active layer is disposed in the non-active area NA as an example.

The thin film transistor GT for a gate driving circuit includes a polycrystalline semiconductor pattern 414, a first gate insulating layer 442, a first gate electrode 416, a plurality of insulating layers, and a first source electrode 417S and a first drain electrode 417D. The polycrystalline semiconductor pattern 414 is disposed on a lower buffer layer 411 formed on the substrate 410. The first gate insulating layer 442 insulates the polycrystalline semiconductor pattern 414. The first gate electrode 416 is disposed on the first gate insulating layer 442 and overlaps a part of the polycrystalline semiconductor pattern 414. The plurality of insulating layers is formed on the first gate electrode 416. The first source electrode 417S and the first drain electrode 417D are disposed on the plurality of insulating layers.

The substrate 410 may be configured as a multi-layer in which an organic layer and an inorganic layer are alternately laminated. For example, in the substrate 410, an organic layer such as polyimide and an inorganic layer such as silicon oxide (SiO₂) may be alternately laminated.

The lower buffer layer 411 is formed on the substrate 410. The lower buffer layer 411 blocks moisture which may permeate from the outside and may be formed by depositing at least one inorganic insulating layer, such as silicon oxide (SiO₂) film.

The polycrystalline semiconductor pattern 414 is formed on the lower buffer layer 411. The polycrystalline semiconductor pattern 414 is used as an active layer of the thin film transistor. The polycrystalline semiconductor pattern 414 includes a first source region 414S and a first drain region 414D which are provided to face each other with the first channel region 414C therebetween.

The polycrystalline semiconductor pattern 414 is insulated by the first gate insulating layer 442. The first gate insulating layer 442 is formed by depositing at least one inorganic insulating layer, such as silicon oxide (SiO₂), on the entire surface of the substrate 410 on which the polycrystalline semiconductor pattern 414 is formed. The first gate insulating layer 442 protects and insulates the polycrystalline semiconductor pattern 414 from the outside.

A first gate electrode 416 which overlaps the first channel region 414C of the polycrystalline semiconductor pattern 414 is formed on the first gate insulating layer 442.

The first gate electrode 416 may be configured by a metal material. For example, the first gate electrode 416 may be formed of a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof, but is not limited thereto.

A plurality of insulating layers may be formed between the first gate electrode 416 and the first source electrode 417S and the first drain electrode 417D.

Referring to FIG. 6A, the plurality of insulating layers may be a first interlayer insulating layer 443 which is in contact with a top surface of the first gate electrode 416, and a second interlayer insulating layer 444, an upper buffer layer 445, a second gate insulating layer 446, and a third interlayer insulating layer 447 which are sequentially laminated thereon.

The first source electrode 417S and the first drain electrode 417D are disposed on the third interlayer insulating layer 447. The first source electrode 417S and the first drain electrode 417D are connected to the polycrystalline semiconductor pattern 414 through the first contact hole CH1 and the second contact hole CH2, respectively. The first contact hole CH1 and the second contact hole CH2 pass through the first gate insulating layer 442, the first interlayer insulating layer 443, the second interlayer insulating layer 444, the upper buffer layer 445, the second gate insulating layer 446, and the third interlayer insulating layer 447. By doing this, the first source region 414S and the first drain region 414D of the polycrystalline semiconductor pattern 414 are exposed.

In the meantime, the driving thin film transistor DT, the first switching thin film transistor ST-1, and the storage capacitor Cst are disposed in the sub pixel of the active area AA.

In the first exemplary embodiment, the driving thin film transistor DT and the first switching thin film transistor ST-1 use the oxide semiconductor pattern as an active layer.

The driving thin film transistor DT includes a first oxide semiconductor pattern 474, a second gate electrode 478 overlapping the first oxide semiconductor pattern 474, a second source electrode 479S, and a second drain electrode 479D.

The oxide semiconductor may be formed of an oxide of a metal, such as zinc (Zn), indium (In), gallium (Ga), tin (Sn), and titanium (Ti), or a combination of a metal, such as zinc (Zn), indium (In), gallium (Ga), tin (Sn), and titanium (Ti) and oxide thereof. To be more specific, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), or indium-zinc-tin oxide (IZTO).

Generally, as an active layer of the driving thin film transistor, a polycrystalline semiconductor pattern which is advantageous for high speed operation is used. However, the driving thin film transistor including the polycrystalline semiconductor pattern may have a problem in that a leakage current occurs in an off-state so that the power is consumed. Specifically, the problem of a leakage current generated in the off-state may be more significant during the low speed operation in which the display device displays a still image, such as a document screen. Accordingly, in the first exemplary embodiment of the present disclosure, a driving thin film transistor which uses an oxide semiconductor pattern advantageous to block the leakage current as an active layer is proposed.

However, when the thin film transistor uses the oxide semiconductor pattern as an active layer, due to a characteristic of the material of the oxide semiconductor, a current fluctuation value is large with respect to a voltage fluctuation value so that many failures may occur in a low grayscale region in which precise current control is necessary. Accordingly, in the first exemplary embodiment, a structure of a driving thin film transistor in which a fluctuation value of the current is relatively insensitive to the fluctuation value of a voltage which is applied to the gate electrode is used.

A structure of a driving thin film transistor will be described with reference to FIGS. 6A to 6C. FIG. 6B is a cross-sectional view of enlarging only a driving thin film transistor DT in FIG. 6A, and FIG. 6C is a circuit diagram illustrating a relationship with a parasitic capacitance generated in the driving thin film transistor DT.

The driving thin film transistor DT includes a first oxide semiconductor pattern 474 located on an upper buffer layer 445, a second gate insulating layer 446 which covers the first oxide semiconductor pattern 474, a second gate electrode 478 which is formed on the second gate insulating layer 446 and overlaps the first oxide semiconductor pattern 474, and a second source electrode 479S and a second drain electrode 479D which are disposed on the second gate electrode 478 and the third interlayer insulating layer 447 which covers the second gate electrode 478. The second gate electrode 478 and the second source electrode 479S and the second drain electrode 479D may be disposed on the same layer.

The first oxide semiconductor pattern 474 which is an active layer includes a second channel region 474C in which charges move, a second source region 474S and a second drain region 474D which are adjacent to the second channel region 474C with the second channel region 474C therebetween.

In the meantime, the first lower conductive pattern BSM-1 is formed below the first oxide semiconductor pattern 474. The first lower conductive pattern BSM-1 suppresses the light introduced from the outside from illuminating onto the first oxide semiconductor pattern 474 to suppress the erroneous operation of the first oxide semiconductor pattern 474 which is sensitive to the external light. Further, the first lower conductive pattern BSM-1 collects hydrogen particles which may be introduced from the lower portion of the first oxide semiconductor pattern 474 to suppress the damage of the first oxide semiconductor pattern 474 from the hydrogen particles. That is, the first lower conductive pattern BSM-1 may be a metal layer including a titanium (Ti) material which may capture the hydrogen particles. For example, the metal layer may be a titanium single layer or a double layer of molybdenum (Mo) and titanium (Ti), or an alloy of molybdenum (Mo) and titanium (Ti). However, it is not limited thereto, and another metal layer including titanium (Ti) is also possible.

Titanium (Ti) captures hydrogen particles diffusing into the upper buffer layer 445 and may suppress the hydrogen particles from reaching the first oxide semiconductor pattern 474.

The first lower conductive pattern BSM-1 is desirably formed vertically below the first oxide semiconductor pattern 474 to overlap the first oxide semiconductor pattern 474. Further, the first lower conductive pattern BSM-1 may be formed to be larger than the first oxide semiconductor pattern 474 to completely overlap the first oxide semiconductor pattern 474.

In the meantime, the second source electrode 479S of the driving thin film transistor DT is electrically connected to the first lower conductive pattern BSM-1. When the first lower conductive pattern BSM-1 is electrically connected to the second source electrode 479S, an additional effect may be achieved as follows. According to another example, the second drain electrode 479D may be electrically connected to the first lower conductive pattern BSM-1.

The second source region 474S and the second drain region 474D of the first oxide semiconductor pattern 474 become conductive, respectively, so that a parasitic capacitance C_{act} is generated in the first oxide semiconductor pattern 474 during an on/off operation. Further, a parasitic capacitance C_{gi} is generated between the second gate electrode 478 and the first oxide semiconductor pattern 474. Further, a parasitic capacitance C_{buf} is generated between the first lower conductive pattern BSM-1 which is electrically connected to the second source electrode 479S and the first oxide semiconductor pattern 474.

The first oxide semiconductor pattern 474 and the first lower conductive pattern BSM-1 are electrically connected by the second source electrode 479S so that the parasitic capacitance C_{act} and the parasitic capacitance C_{buf} are connected in parallel and the parasitic capacitance C_{act} and the parasitic capacitance C_{gi} are connected in series. Further, when the gate voltage of V_{gat} is applied to the second gate electrode 478, an effective voltage V_{eff} which is actually applied to the first oxide semiconductor pattern 474 establishes the following Equation 1.

$$Δ Veff = \frac{Cgi}{Cgi + Cbuf + Cact} * Δ Vgat \qquad [ Equation 1 ]$$

Accordingly, the effective voltage V_{eff} which is applied to the second channel region 474C is in inverse proportion to the parasitic capacitance C_{buf}, so that the effective voltage applied to the first oxide semiconductor pattern 474 may be adjusted by adjusting the parasitic capacitance C_{buf}.

That is, when the first lower conductive pattern BSM-1 is disposed to be close to the first oxide semiconductor pattern 474 to increase the parasitic capacitance C_{buf}, an actual current value flowing through the first oxide semiconductor pattern 474 may be reduced.

When the effective current value flowing through the first oxide semiconductor pattern 474 is reduced, it means that an s-factor may be increased so that a controllable range of the driving thin film transistor DT which may be controlled by the gate voltage V_{gat} which is actually applied to the second gate electrode 478 is increased.

That is, when the second source electrode 479S of the driving thin film transistor DT and the first lower conductive pattern BSM-1 are electrically connected, and the first lower conductive pattern BSM-1 is disposed to be close to the first oxide semiconductor pattern 474, the organic light emitting diode may be precisely controlled even at a low gray scale. Therefore, the problem of screen stain which is frequently generated at a low gray scale may be solved.

Accordingly, in the first exemplary embodiment of the present disclosure, the parasitic capacitance C_{buf} generated between the first oxide semiconductor pattern 474 and the first lower conductive pattern BSM-1 may be larger than the parasitic capacitance C_{gi} generated between the second gate electrode 478 and the first oxide semiconductor pattern 474. On the other hand, the parasitic capacitance C_{gi} generated between the second gate electrode 478 and the first oxide semiconductor pattern 474 may be smaller than the parasitic capacitance C_{buf} generated between the first oxide semiconductor pattern 474 and the first lower conductive pattern BSM-1.

Here, the s-factor refers to a reciprocal value of a current variance for a gate voltage variance in an on/off transition period of the thin film transistor. That is, it may be a reciprocal value of the slope of the curve in the characteristic graph of drain current to gate voltage (V-I curve graph).

A small s-factor means that the slope of the characteristic graph of drain current to gate voltage is large so that the thin film transistor is turned on even at a low voltage, and thus the switching characteristic of the thin film transistor is improved. In contrast, it reaches a threshold voltage in a short time so that it may be difficult to express a sufficient gray scale.

A large s-factor means that the slope of the characteristic graph of drain current to gate voltage is small. Therefore, an on/off response speed of the thin film transistor is degraded even though the switching characteristic of the thin film transistor is degraded, it reaches the threshold voltage for a relatively long period of time, so that the sufficient gray scale may be expressed.

Specifically, the first lower conductive pattern BMS-1 is inserted into the upper buffer layer 445 to be disposed to be close to the first oxide semiconductor pattern 474. That is, a vertical distance between the first oxide semiconductor pattern 474 and the first lower conductive pattern BSM-1 is shorter than a vertical distance between the first oxide semiconductor pattern 474 and the second gate electrode 478 to increase the s-factor value of the driving thin film transistor.

The first lower conductive pattern BSM-1 is desirably formed vertically below the first oxide semiconductor pattern 474 to overlap the first oxide semiconductor pattern 474. Further, the first lower conductive pattern BSM-1 may be formed to be larger than the first oxide semiconductor pattern 474 to completely overlap the first oxide semiconductor pattern 474.

In the meantime, the second gate electrode 478 of the driving thin film transistor DT is insulated by the third interlayer insulating layer 447, and the second source electrode 479S and the second drain electrode 479D are formed on the third interlayer insulating layer 447.

The second source electrode 479S and the second drain electrode 479D are connected to the second source region 474S and the second drain region 474D through the third contact hole CH3 and the fourth contact respectively. Further, the first lower conductive pattern BSM-1 is connected to the second source electrode 479S through a fifth contact hole CH5.

In the meantime, the first switching thin film transistor ST-1 includes a second oxide semiconductor pattern 432, a third gate electrode 433, a third source electrode 434S, and a third drain electrode 434D.

The second oxide semiconductor pattern 432 includes a third channel region 432C, a third source region 432S and a third drain region 432D which are adjacent to the third channel region 432C with the third channel region 432C therebetween.

The third gate electrode 433 is located on the second oxide semiconductor pattern 432 with the second gate insulating layer 446 interposed therebetween.

The third source electrode 434S and the third drain electrode 434D may be disposed on the same layer as the second source electrode 479S and the second drain electrode 479D. That is, the second source/drain electrodes 479S and 479D and the third source/drain electrodes 434S and 434D may be disposed on the third interlayer insulating layer 447.

However, the third source/drain electrodes 434S and 434D may be disposed on the same layer as the third gate electrode 433. That is, the third source/drain electrodes 434S and 434D may be simultaneously formed on the second gate insulating layer 446 with the same material.

Further, the second lower conductive pattern BSM-2 may be disposed below the second oxide semiconductor pattern 432.

The second lower conductive pattern BSM-2 may be electrically connected to the third gate electrode 433 to configure a dual gate.

In the meantime, referring to FIG. 6A, the sub pixel includes a storage capacitor Cst.

The storage capacitor Cst stores a data voltage which is applied through the data line for a predetermined period and then supplies the stored data voltage to the organic light emitting diode.

The storage capacitor Cst includes two corresponding electrodes and a dielectric material disposed therebetween. The storage capacitor Cst includes a first electrode 450A of a storage capacitor Cst disposed on the substrate 410 and a second electrode 450B of a storage capacitor Cst which overlaps the first electrode 450A of the storage capacitor Cst to be provided to face thereto.

At least one insulating layer may be interposed between the first electrode 450A of the storage capacitor Cst and the second electrode 450B of the storage capacitor Cst.

The second electrode 450B of the storage capacitor Cst may be electrically connected to the second source electrode 479S.

In the meantime, referring to FIG. 6A, a first planarization layer PLN1 may be formed on the substrate 410 on which the driving thin film transistor DT and the first switching thin film transistor ST-1 are disposed. The first planarization layer PLN1 may be configured by an organic material such as photo acryl but may also be configured by a plurality of layers formed of an inorganic layer and an organic layer. The connection electrode 455 is formed on the first planarization layer PLN1. The connection electrode 455 electrically connects the anode electrode 461 which is one component of the light emitting diode part 460 and the driving thin film transistor DT through a ninth contact hole CH9 formed in the first planarization layer PLN1.

Further, a conductive film used to form the connection electrode 455 may configure a part of various link lines disposed in the bending area BA.

A second planarization layer PLN2 may be formed on the connection electrode 455. The second planarization layer PLN2 may be formed by an organic material such as photo acryl, which is the same as the first planarization layer PLN1 but may also be configured by a plurality of layers formed of an inorganic layer and an organic layer.

The anode electrode 461 is formed on the second planarization layer PLN2. The anode electrode 461 is electrically connected to the connection electrode 455 through a tenth contact hole CH10 formed in the second planarization layer PLN2.

The anode electrode 461 is formed by a single layer or a plurality of layers, formed of metal such as Ca, Ba, Mg, Al, and Ag, or an alloy thereof, to be connected to the second drain 479D of the driving thin film transistor DT to apply an image signal from the outside.

In addition to the anode electrode 461, in the non-active area NA, the anode connection electrode 457 which electrically connects a common voltage line VSS and the cathode electrode 463 may be further provided.

A bank layer 456 is formed on the second planarization layer PLN2. The bank layer 456 is a sort of partition to divide each sub pixels to suppress light of specific color output from adjacent sub pixels from being mixed and output.

An organic light emitting layer 462 is formed on a surface of the anode electrode 461 and a partial area of the inclined surface of the bank layer 456. The organic light emitting layer 462 may be an R-organic light emitting layer which emits red light, a G-organic light emitting layer which emits green light, and a B-organic light emitting layer which emits blue light which are formed in each sub pixel. Further, the organic light emitting layer 462 may be a W-organic light emitting layer which emits white light.

The organic light emitting layer 462 may include an electron injection layer and a hole injection layer which inject electrons and holes, respectively, to the light emitting layer, and an electron transport layer and a hole transport layer which transport the injected electrons and holes, respectively, to the organic layer, as well as the light emitting layer.

A cathode electrode 463 is formed on the organic light emitting layer 462. The cathode electrode 463 may be formed of a transparent conductive material such as indium tin oxide (ITO) or indium zinc oxide (IZO), or metal with a thin thickness to which visible ray transmits but is not limited thereto.

An encapsulation layer part 470 is formed on the cathode electrode 463. The encapsulation layer part 470 may be configured by a signal layer configured by an inorganic layer, configured by a double layer of an inorganic layer/organic layer, and also configured by a triple layer of an inorganic layer/organic layer/inorganic layer. The inorganic layer may be configured by an inorganic material such as SiNx and SiX but is not limited thereto. Further, the organic layer may be formed of an organic material such as polyethylene terephthalate, polyethylene naphthalate, polycarbonate, polyimide, polyethylene sulfonate, polyoxymethylene, and polyarylate, or a mixture thereof, but is not limited thereto.

In FIG. 6A, as an exemplary embodiment of the encapsulation layer part 470, it is disclosed that a triple layer of an inorganic layer 471/organic layer 472/inorganic layer 473 is configured.

A cover glass (not illustrated) is disposed on the encapsulation layer part 470 to be attached by an adhesive layer (not illustrated). As the adhesive layer, any material which has a good adhesiveness, heat resistance, and water resistance may be used, but in the present disclosure, a thermosetting resin, such as an epoxy-based compound, an acrylate-based compound, or an acrylic rubber, may be used. Further, as the adhesive, a photo curable resin may be used and, in this case, light such as ultraviolet ray is irradiated onto the adhesive layer to harden the adhesive layer.

The adhesive layer may bond not only the substrate 410 and the cover glass (not illustrated) but may also serve as an encapsulant for suppressing moisture from permeating into the organic electroluminescence display device.

The cover glass (not illustrated) is an encapsulation cap for encapsulating the organic light emitting display device and may use a protective film such as a polystyrene (PS) film, a polyethylene (PE) film, a polyethylene naphthalate (PEN) film, and a polyimide (PI) film, or use a glass.

It will be apparent to those skilled in the art that various modifications and variations can be made in the thin film transistor array substrate an oxide including semiconductor pattern and a display device including the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor array substrate, comprising:
a substrate including an active area and a non-active area disposed in the vicinity of the active area; and
a plurality of pixels disposed in the active area,
wherein each pixel includes a plurality of sub pixels, and each sub pixel includes a driving thin film transistor including an oxide semiconductor pattern, and the driving thin film transistor in the pixel includes sub pixels having different ratios of a width to a length of a channel of the driving thin film transistor.

2. The thin film transistor array substrate according to claim 1, wherein the plurality of sub pixels includes red, green, and blue sub pixels, and a ratio of a width to a length of a channel of the driving thin film transistor included in the blue sub pixel is smallest.

3. The thin film transistor array substrate according to claim 2, wherein the length of the channel of the driving thin film transistor included in the blue sub pixel among the pixel is largest.

4. The thin film transistor array substrate according to claim 1, wherein the driving thin film transistor includes:
a first oxide semiconductor pattern disposed on the substrate;
a first gate electrode which overlaps a part of the first oxide semiconductor pattern;
a first lower conductive pattern overlapping a part of the first oxide semiconductor pattern and disposed below the first oxide semiconductor pattern; and
a first source electrode and a first drain electrode which are electrically connected to the first oxide semiconductor pattern, and
any one of the first source electrode and the first drain electrode is electrically connected to the first lower conductive pattern.

5. The thin film transistor array substrate according to claim 4, wherein a parasitic capacitance generated between the first oxide semiconductor pattern and the first gate electrode is smaller than a parasitic capacitance generated between the first oxide semiconductor pattern and the first lower conductive pattern.

6. The thin film transistor array substrate according to claim 5, further comprising:
a light emitting diode part including:
an anode electrode which is connected to the driving thin film transistor;
a cathode electrode corresponding to the anode electrode; and
a light emitting layer disposed between the anode electrode and the cathode electrode.
